(19) United States
(12) Patent Application Publication
(10) Pub. No.: US 2006/0141678 A1
(43) Pub. Date: Jun. 29, 2006

(54) Forming a nanotube switch and structures formed thereby

(76) Inventors: Stephen Montgomery, Seattle, WA (US); Tomm Aldridge, Olympia, WA (US); Nels Jewell-Larsen, Dupont, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/027,808

(22) Filed: Dec. 29, 2004

(51) Int. Cl. H01L 21/82

(52) U.S. Cl. 438/129

(57) ABSTRACT

Methods of forming a microelectronic structure are described. Embodiments of those methods include providing a substrate comprising a power pad, and attaching a nanotube comprising at least one side chain to the power pad.

### BACKGROUND OF THE INVENTION

Current power delivery designs may be inefficient with respect to power delivery, and in some instances may deliver at an efficiency of only about fifty percent.

The power that is lost to these inefficiencies may be unavailable to perform any useful work, and may further contribute to system thermal problems, such in a microelectronic packaging system, for example.

### BRIEF DESCRIPTION OF THE DRAWINGS

While the specification concludes with claims particularly pointing out and distinctly claiming certain embodiments of the present invention, the advantages of this invention can be more readily ascertained from the following description of the invention when read in conjunction with the accompanying drawings in which:

FIGS. 1a-1e represent methods of forming structures according to an embodiment of the present invention.

FIGS. 2a-2b represent a system according to another embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming and utilizing a microelectronic structure, such as a nanotube switching structure, are described. Those methods may comprise providing a substrate comprising a power pad, and attaching a nanotube comprising at least one side chain to the power pad.

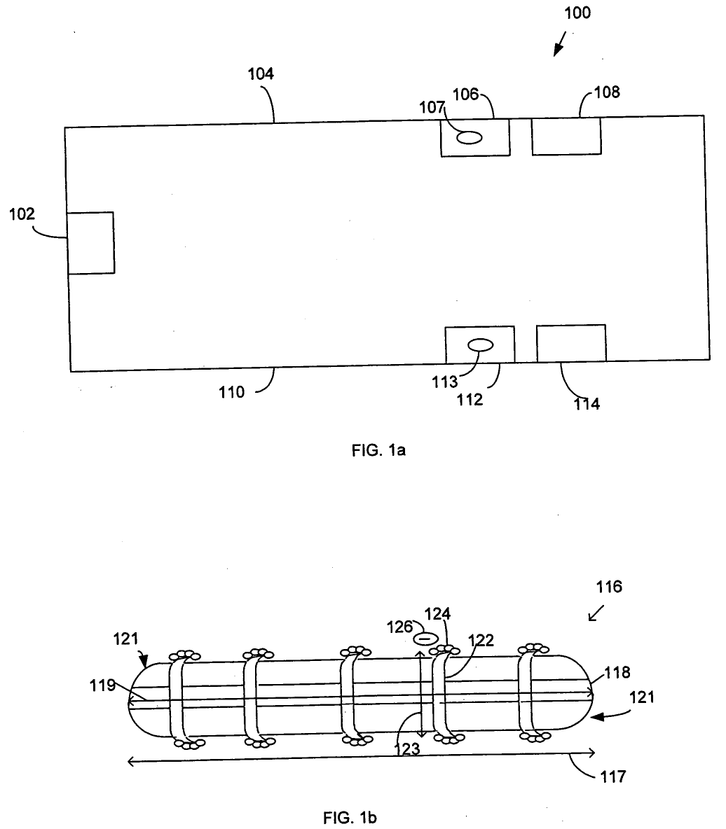

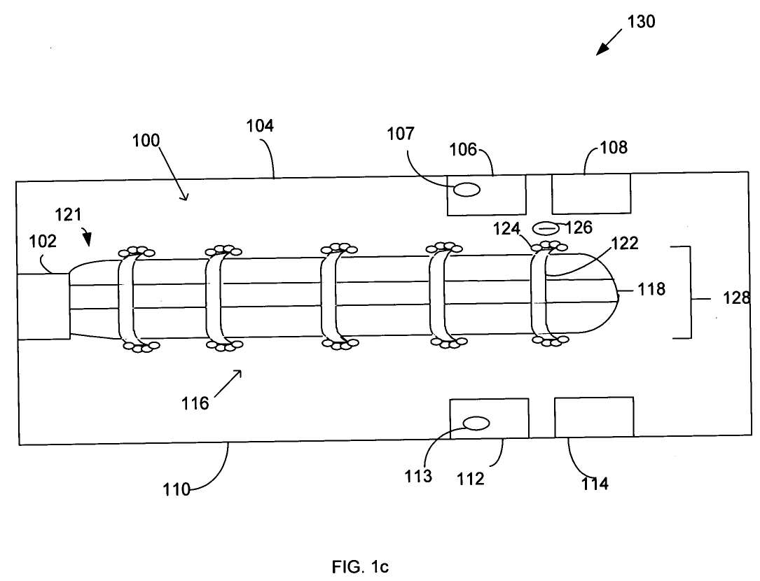

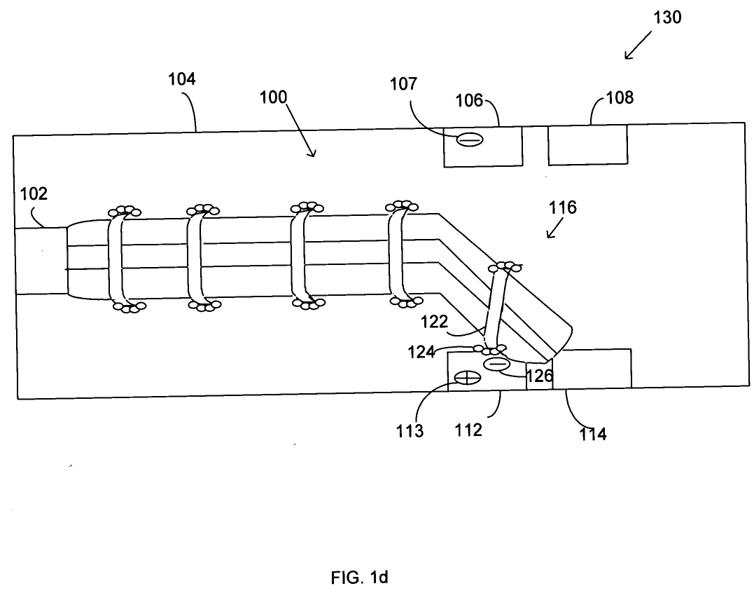

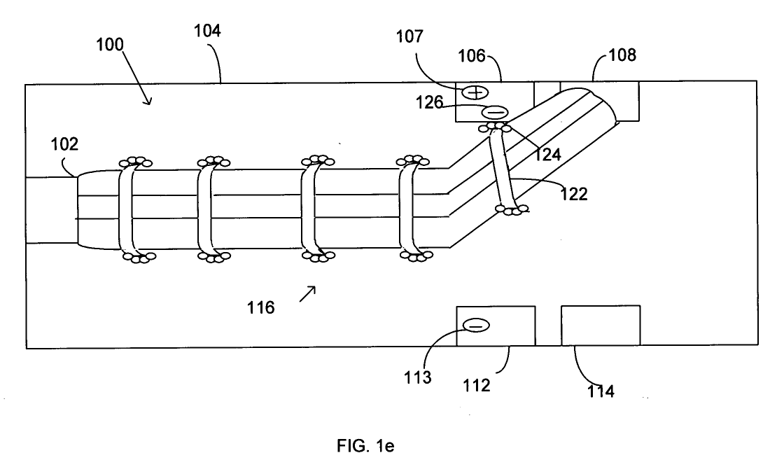

FIGS. 1a-1e illustrate an embodiment of a method of forming a microelectronic structure, such as a nanotube switching structure, for example. FIG. 1a illustrates a substrate 100. In one embodiment, the substrate 100 may comprise a layer of a printed circuit board (PCB), as is well known in the art. In another embodiment, the substrate 100 may comprise a layer of a microelectronic circuit, as is well known in the art. In one embodiment, the substrate 100 may further comprise comprise a power pad 102. In one embodiment, the power pad 102 may comprise any type of structure that may connect to a power and/or current source, as are well known in the art. The power pad 102 may comprise a conductive material, such as gold or copper, in some embodiments, for example.

The substrate 100 may comprise a first side 104 and a second side 110. The first side 104 of the substrate 100 may comprise a first switch pad 106 and a first current pad 108. The first switch pad 106 may comprise any conductive material that may comprise a first charge state 107, such as a positive charge state, a negative charge state, or a neutral charge state, for example. In one embodiment, the first switch pad 106 may receive the first charge state 107 from a source (not shown), such as a voltage source, as are well known in the art. In one embodiment, the first switch pad 106 may comprise a copper or gold material. The first current pad 108 may comprise any type of conductive material as well. The first current pad 108 may further be connected to an interconnect pad (not shown), such as an interconnect pad within an electrical circuit of a microelectronic device, for example.

The second side 110 of the substrate 100 may comprise a second switch pad 112 (similar to the switch pad 106) and a second current pad 114 (similar to the current pad 108). The second switch pad 112 may comprise a second charge state 113, that may comprise a positive charge state, a negative charge state, or a neutral charge state. In one embodiment, the second switch pad 112 may receive the second charge state 113 from a source (not shown), such as a voltage source, as is well known in the art.

FIG. 1b depicts a nanotube 116, that may comprise a carbon nanotube in one embodiment. The nanotube 116 may comprise a single walled and/or a mutilwalled nanotube 116 in some embodiments. In one embodiment, the nanotube 116 may comprise a conductive nanotube, such as a metallic nanotube, as are well known in the art. In one embodiment, the nanotube 116 may comprise a diameter of about one nanometer to about 10 nanometers, and a length of about 1 micron to about 10 microns. The nanotube 116 may comprise terminal ends 121, as are well known in the art.

In one embodiment, the nanotube 116 may comprise a backbone structure 118. The backbone structure 118 may comprise a backbone molecule in one embodiment, such as but not limited to polyarylene ethynylene (PPE), and/or other single chain polymers. In one embodiment, the backbone structure 118 may be grafted onto the nanotube 116 by methods well known to those skilled in the art, such as but not limited to coating the nanotube 116 with the backbone structure 118, wherein the backbone structure 118 may be held in place on the nanotube 116 by Vander Walls forces, as are well known in the art. In one embodiment, the backbone structure 118 may be attached to the nanotube 116 such that a length 119 of the backbone structure 118 may be substantially parallel to a length 117 of the nanotube 116.

The nanotube 116 may further comprise at least one side chain 122. In one embodiment, the at least one side chain 122 may be attached to the backbone structure 118 by methods well known in the art. In one embodiment, the at least one side chain 122 may be attached to the backbone structure 118 such that a length 123 of the at least one side chain 122 may be substantially perpendicular to the length 119 of the backbone structure 118.

The at least one side chain 122 may comprise various types of molecules, but in some embodiments may comprise fluorine, oxygen and/or iron. In one embodiment, the at least one side chain 122 may further comprise atoms 124. In one embodiment, the atoms may comprise electronegative atoms (i.e. atoms that may comprise electrons that may group around the atoms, thereby creating a local negative charge). The atoms 124 may in some embodiments comprise polar atoms, such as flourine and/or oxygen. The at least one side chain 122 may comprise a side chain charge state 126, which in one embodiment may comprise a negative side chain charge state 126.

A terminal end 121 of the nanotube 116 may be attached to the power pad 102 of the substrate 100 to form a nanotube switching structure 130 (FIG. 1c). In one embodiment, the terminal end 121 of the nanotube 116 may be attached to the power pad 102 such that a portion of the nanotube 116 comprising the at least one side chain 122 may be substantially between the first switch pad 106 and the second switch pad 112 of the substrate 100. The terminal end 121 of the nanotube 116 may be attached to the power pad 102 utilizing any method of attachment known in the art, such as but not limited to a fusing method, as is well known in the art.

In one embodiment, the first charge state 107 and the second charge state 113 of the first switch pad 106 and the second switch pad 112 respectively, may comprise the same sign. For example, in one embodiment, the first charge state 107 and the second charge state 113 may both comprise either a positive sign or a negative sign. In one embodiment, this may be accomplished by applying either a positive or a negative voltage to both the first switch pad 106 and the second switch pad 112. In this manner, the first charge state 107 and the second charge state 113 may be set to a specific charge state, or sign, by applying the desired voltage according to particular design requirements.

In one embodiment, the side chain charge state 126 may comprise a negative sign. Because the first charge state 107 and the second charge state 113 may comprise the same sign, the negatively charged at least one side chain 122 may be disposed between the first switch pad 106 and the second switch pad 112, due to the electrostatic forces between the negative charge of the side chain charge state 126 and the first charge state 107 and the second charge state 113.

That is, the negative charge of the side chain charge state 126 may be equally attracted (or repelled) to the first switch pad 106 and the second switch pad 112. Thus, the at least one side chain 122, and therefore the nanotube 116 attached thereto, may be disposed in an approximately midpoint position 128 between the first switch pad 106 and the second switch pad 112.

It will be understood by those skilled in the art that in other embodiments the side chain charge state 126 may comprise a positive sign and may be disposed in an approximately midpoint position 128 between the first switch pad 106 and the second switch pad 112, due to electrostatic attractive forces, as are well known in the art. When the nanotube switching structure 130 is in the approximate midpoint position 128, it may not make contact with either the first switch pad 106 or the second switch pad 112, so that there may not be a conductive path between the power pad 102 and either the first or second switch pads 106, 112. In one embodiment, the approximate midpoint position 128 may comprise any position between the switch pads 106, 112 that does not make contact with the switch pads 106, 112.

In another embodiment, the second charge state 113 of the second switch pad 112 may comprise a second charge state 113 that may be of substantially the opposite sign as the side chain charge state 126, and the first charge state 107 of the first switch pad 106 may comprise a charge state that is substantially the same as the side chain charge state 126. For example, in one embodiment, the side chain charge state 126 may comprise a negative charge state, the first charge state 107 may comprises a negative first charge state 107 and the second charge state 113 may comprise a positive second charge state 113 (FIG. 1d).

In one embodiment, the negatively charged at least one side chain 122 may be electrically attracted to the positively charged second switch pad 112. In one embodiment, because the nanotube 116 may be attached to the at least one side chain 122, the electrostatic force between the negatively charged at least one side chain 122 and the positevly charged second switch pad 112 may cause the nanotube 116 to bend to make contact with the second switch pad 112 and the second current pad 114.

The nanotube 116 may be capable of bending easily since nanotubes may posses high elasticity and may exhibit little or no plastic deformation and/or fatigue, so that they may return to their previous shape relatively quickly, as is well known in the art. In this manner, a conductive path may be made between the power pad 102 and the second switch pad 112 and the second current pad 114, through the nanotube 116. In addition, in one embodiment, the nanotube 116 may comprise a conduction of about 10⁻¹³ amperes per centimeter squared, and may be extremely efficient, exhibiting little heat loss and maintaining high power efficiency. In some embodiments, the power efficiency of the nanotube switching structure may exceed about 80% power efficiency.

In another embodiment, the first charge state 107 of the first switch pad 106 may be set to a sign opposite the side chain charge state 126, and the second charge state 113 of the second switch pad 112 may be set to a charge state substantially the same as the side chain charge state 126. For example, the first switch state 107 may comprise a positive charge state, the second charge state 113 may comprise a negative charge state and the side chain charge state 126 may comprise a negative charge state (FIG. 1e). The nanotube 116 may then be electrostatically attracted to and thus bend to make contact with the first switch pad 106. A conductive path may then be made between the power pad 102, the first switch pad 107 and the first current pad 108.

The nanotube 116 may bend from one position (for example from a position wherein the nanotube makes contact to either the first switch pad 106 or the second switch pad 112) to the approximately midpoint position 128 (see FIG. 1c), due to the electrostatic attraction between the at least one side chain 122 and the switch pads 106, 112. Thus, the nanotube 116 of the nanotube switching structure 130 may bend to a neutral midpoint position 128 (and provide no conductive path to the switch pads 106, 112) or it may bend and make contact to either of the switch pads 106, 112, thus creating a conductive path from the power pad 102 to either of the switch pads 106, 112. The particular switch pad 106, 112 that the nanotube 116 may contact will depend on the design needs of the particular application.

It will be understood by those skilled in the art that a plurality of the nanotube switching structures 130 may be employed within a particular application, such as but not limited to a circuit design application, for example. Because the nanotube 116 of the nanotube switching structure 130 may quickly switch between switch pads 106, 112 (by virtue of the nanotube 116 comprising an extremely small size), the nanotube switching structure 130 may be capable of switching large amounts of current at very high rates. In one embodiment, the nanotube 116 of the nanotube switching structure 130 may switch between switching pads 106, 112 about as fast as the clock speed of a central processing unit (CPU). In some embodiments, the switching speed of the nanotube switching structure 130 may comprise a speed of about 1 to about 800 or greater MHz.

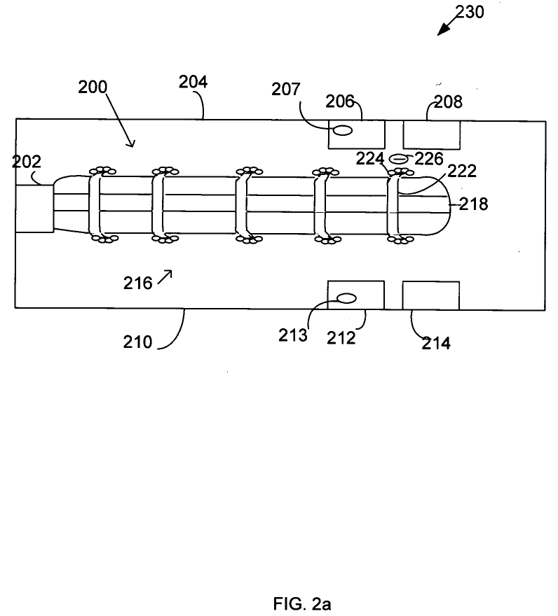

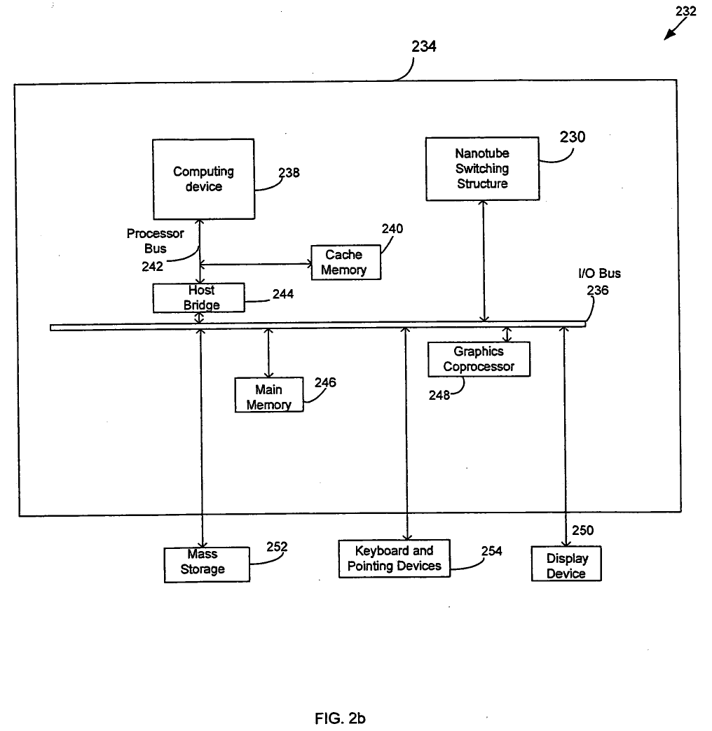

FIG. 2a depicts a nanotube switching structure 230, similar to the nanotube switching structure 130 of FIG. 1c, for example. A nanotube 216 may be disposed on a substrate 200 that may be attached to a power pad 202. The substrate 200 may comprise a layer of a printed circuit (PC) board in one embodiment, or may comprise a layer in an integrated circuit in other embodiments. The nanotube 116 may comprise a backbone structure 218 and at least one side chain 222. The at least one side chain 222 may comprise atoms 124, that may comprise a side chain charge state 226.

A first side 204 of the substrate 200 may comprise a first switch pad 206, a first current pad 208, and a second side 210 of the substrate 200 may comprise a second switch pad 212 and a second current pad 214. The first switch pad 206 and the second switch pad 212 may comprise a first charge state 207 and a second charge state 213 respectively. In one embodiment, the first current pad 208 and/or the second current pad 214 may be attached to an interconnect pad (not shown) as are known in the art, and/or may be coupled to various other components within a microelectronic device, for example.

FIG. 2b is a diagram illustrating an exemplary system 232 capable of being operated with methods for fabricating a microelectronic structure, such as the nanotube switching structure 230 of FIG. 2a for example. It will be understood that the present embodiment is but one of many possible systems in which the nanotube switching structures of the present invention may be used.

In the system 232, the nanotube switching structure 230 may be communicatively coupled to a printed circuit board (PCB) 234 by way of an I/O bus 236. The communicative coupling of the nanotube switching structure 230 may be established by physical means, such as through the use of a package and/or a socket connection to mount the nanotube switching structure 230 to the PCB 234 (for example by the use of a chip package and/or a land grid array socket). The nanotube switching structure 230 may also be communicatively coupled to the PCB 234 through various wireless means (for example, without the use of a physical connection to the PCB), as are well known in the art.

The system 232 may include a computing device 238, such as a processor, and a cache memory 240 communicatively coupled to each other through a processor bus 242. The processor bus 242 and the I/O bus 236 may be bridged by a host bridge 244. Communicatively coupled to the I/O bus 236 and also to the nanotube switching structure 230 may be a main memory 246. Examples of the main memory 246 may include, but are not limited to, static random access memory (SRAM) and/or dynamic random access memory (DRAM), and/or some other state preserving mediums. The system 232 may also include a graphics coprocessor 248, however incorporation of the graphics coprocessor 248 into the system 232 is not necessary to the operation of the system 232. Coupled to the I/O bus 236 may also, for example, be a display device 250, a mass storage device 252, and keyboard and pointing devices 254.

These elements perform their conventional functions well known in the art. In particular, mass storage 252 may be used to provide long-term storage for the executable instructions for a method for forming nanotube switching structures in accordance with embodiments of the present invention, whereas main memory 246 may be used to store on a shorter term basis the executable instructions of a method for forming nanotube switching structures in accordance with embodiments of the present invention during execution by computing device 238. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 246 may supply the computing device 238 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures are well known in the art. Therefore, the Figures provided herein illustrate only portions of an exemplary microelectronic structure that pertains to the practice of the present invention. Thus the present invention is not limited to the structures described herein.

What is claimed is:

1. A method of forming a structure comprising:
providing a substrate comprising a power pad; and
attaching a nanotube comprising at least one side chain to the power pad.

2. The method of claim 1 further comprising wherein the nanotube comprises a backbone structure, wherein the least one side chain is attached to the backbone structure.

3. The method of claim 2 wherein the backbone structure may comprise PPE.

4. The method of claim 1 further comprising wherein a length of the backbone structure is substantially parallel to a length of the nanotube.

5. The method of claim 1 further comprising wherein the at least one side chain comprises a side chain charge state.

6. The method of claim 1 further comprising wherein the at least one side chain comprises an electronegative side chain.

7. The method of claim 1 further comprising wherein the substrate comprises a first switch pad and a first current pad disposed on a first side of the substrate.

8. The method of claim 7 further comprising wherein the substrate comprises a second switch pad and a second current pad disposed on a second side of the substrate.

9. The method of claim 8 further comprising wherein the second switch pad comprises a second charge state of substantially opposite sign as the side chain charge state, and wherein the first switch pad comprises a first charge state that is substantially the same sign as the side chain charge state.

10. The method of claim 9 further comprising wherein the nanotube bends to make contact with the second switch pad and the second current pad.

11. The method of claim 10 wherein the nanotube bends to make contact with the second switch pad and the second current pad comprises wherein the at least one side chain of the at least one nanotube is electrically attracted to and makes contact with the second switch pad and the second current pad.

12. The method of claim 10 further comprising wherein a conductive path is made between the power pad and the second switch pad and the second current pad.

13. A method comprising:
providing a substrate comprising a power pad, a nanotube attached to the power pad, wherein the nanotube comprises at least one side chain, a first switch pad disposed on a first side of the substrate and a second switch pad disposed on a second side of the substrate; and
setting the first switch pad to a first charge state substantially equal to a side chain charge state, wherein the nanotube bends to make contact with the second switch pad.

14. The method of claim 13 further comprising wherein the second switch pad comprises a second charge state substantially opposite of the side chain charge state.

15. The method of claim 13 further comprising setting the first charge state and a second charge state of the second switch pad to substantially the same sign, wherein the nanotube bends to an approximately midpoint position between the second switch pad and the first switch pad.

16. The method of claim 13 further comprising setting the first charge state to a sign opposite the side chain charge state, wherein the nanotube bends to make contact with the first switch pad.

17. The method of claim 16 further comprising setting a second charge state of the second switch pad to a sign substantially equal to the side chain charge state.

18. The method of claim 17 further comprising wherein a conductive path is made between the power pad, the first switch pad and a first current pad disposed on the first side of the substrate.

19. A structure comprising:
a substrate comprising a power pad; and
a nanotube attached to the power pad, wherein the nanotube comprises at least one side chain.

20. The structure of claim 19 further comprising a backbone structure, wherein a length of the backbone structure is disposed substantially parallel to a length of the nanotube, and wherein a length of the at least one side chain is disposed on the backbone structure substantially perpendicular to the length of the backbone structure.

21. The structure of claim 20 wherein the backbone structure comprises PPE.

22. The structure of claim 19 wherein the at least one side chain comprises an electronegative side chain.

23. The structure of claim 22 wherein the electronegative side chain comprises a side chain comprising a local negative charge.

24. The structure of claim 19 further comprising wherein the substrate comprises a first switch pad and a first current pad disposed on a first side of the substrate.

25. The structure of claim 24 further comprising wherein the substrate comprises a second switch pad and a second current pad disposed on a second side of the substrate.

26. The structure of claim 25, wherein the nanotube is disposed between the first switch pad and the second switch pad, and is capable of bending to make contact with at least one of the first switch pad and the second switch pad.

27. The structure of claim 26, wherein the nanotube is capable of making contact with at least one of the first switch pad and the second switch pad at a speed approximately equal to a clock speed of a CPU.

28. The structure of claim 19, wherein the nanotube comprises a diameter of about one nanometer to about 10 nanometers, and a length of about 1 micron to about 20 microns.

29. A system comprising:
a nanotube switching structure comprising a power pad and a nanotube attached to the power pad, wherein the nanotube is disposed between a first switch pad and a second switch pad, and wherein the nanotube is capable of bending to make contact with at least one of the first switch pad and the second switch pad;
a PCB communicatively coupled to the nanotube switching structure; and
a DRAM communicatively coupled to the nanotube switching structure.

30. The system of claim 29 wherein the nanotube further comprises at least one side chain, wherein the at least one side chain is capable of being electrically attracted to at least one of the first switch pad and the second switch pad.

31. The system of claim 29 further comprising a backbone structure, wherein a length of the backbone structure is disposed substantially parallel to a length of the nanotube, and wherein a length of the at least one side chain is disposed on the backbone structure substantially perpendicular to the length of the backbone structure.
